(19) United States
(12) Patent Application Publication
(10) Pub. No.: US 2007/0210887 A1
(43) Pub. Date: Sep. 13, 2007

(54) TRANSFORMER AND ELECTRONIC DEVICE UTILIZING THE SAME

(75) Inventors: CHENG-CHUEH TSAI, Shenzhen (CN); CHU-LUNG CHIEN, Shenzhen (CN); YI-MEI LIU, Shenzhen (CN); YI-HSUN LIN, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,149

(22) Filed: Jun. 28, 2006

(30) Foreign Application Priority Data
Mar. 10, 2006 (CN) 200620056234.9

(51) Int. Cl. H01F 27/02

(52) U.S. Cl. 336/96

(57) ABSTRACT

A transformer (10), coupled to a circuit board (20) defining a receiving hole (210), includes a base (110) having a first end portion (110a) and an oppositely disposed second end portion (110b), a bobbin assembly (120) disposed between the first end portion and the second end portion, and a post (140) disposed on the base. The post is received in the receiving hole for positioning the transformer on the circuit board.

### FIELD OF THE INVENTION

The present invention pertains to electronic devices, and particularly to an electronic device with a transformer having a plurality of positioning posts.

### DESCRIPTION OF RELATED ART

Recently, with the development of electronic technology, electronic devices are getting more and more complicated with a large number of electronic components. In order to assemble the electronic components onto a circuit board of the electronic device, one common technique involved is called surface mounting technology (SMT). In the SMT process, much attention must be taken to correctly locate the electronic components on the circuit board so that leads of each component are correctly aligned with corresponding pads of the circuit board.

Commonly, in the SMT process, the leads of the small electronic components, such as SMT resistors, capacitors, chips and so on, can be easily aligned with the corresponding pads of the circuit board. However, difficulties may be encountered when aligning the leads of larger electronic components, such as transformers, connectors, CPU sockets and so on, since these components are heavy enough and difficult to keep positioned on the circuit board when soldering in a reflow oven. Consequently, the larger components may shift during soldering. When this happens, connections of the leads of the components with the pads of the circuit board may be faulty, thus causing the electronic device to fail in operation.

Therefore, a heretofore unaddressed need exists in the industry to overcome the aforementioned deficiencies and inadequacies.

### SUMMARY OF THE INVENTION

One aspect of the invention provides a transformer. The transformer, coupled to a circuit board defining a receiving hole, includes a base having a first end portion and a second end portion opposite to the first end portion, a bobbin assembly disposed between the first end portion and the second end portion, and at least one post disposed on the base. Wherein the at least one post is received in the receiving hole for positioning the transformer on the circuit board.

Another aspect of the invention provides an electronic device. The electronic device includes a circuit board defining a receiving hole, and a transformer coupled to the circuit board. The transformer includes a base having a first end portion and a second end portion opposite to the first end portion, a bobbin assembly disposed between the first end portion and the second end portion, and at least one post disposed on the base. Wherein the at least one post is received in the receiving hole for positioning the transformer on the circuit board.

Other advantages and novel features will become more apparent from the following detailed description of preferred embodiments when taken in conjunction with the accompanying drawings, in which:

### BRIEF DESCRIPTION OF THE DRAWINGS

FIG. 1 is an exploded, isometric view of an electronic device of an exemplary embodiment of the present invention, the electronic device including a transformer and a circuit board;

FIG. 2 is an isometric view of a transformer of another exemplary embodiment of the present invention;

FIG. 3 is an isometric view of a transformer of a further exemplary embodiment of the present invention; and

FIG. 4 is an isometric view of a transformer of a still further exemplary embodiment of the present invention.

### DETAILED DESCRIPTION OF THE INVENTION

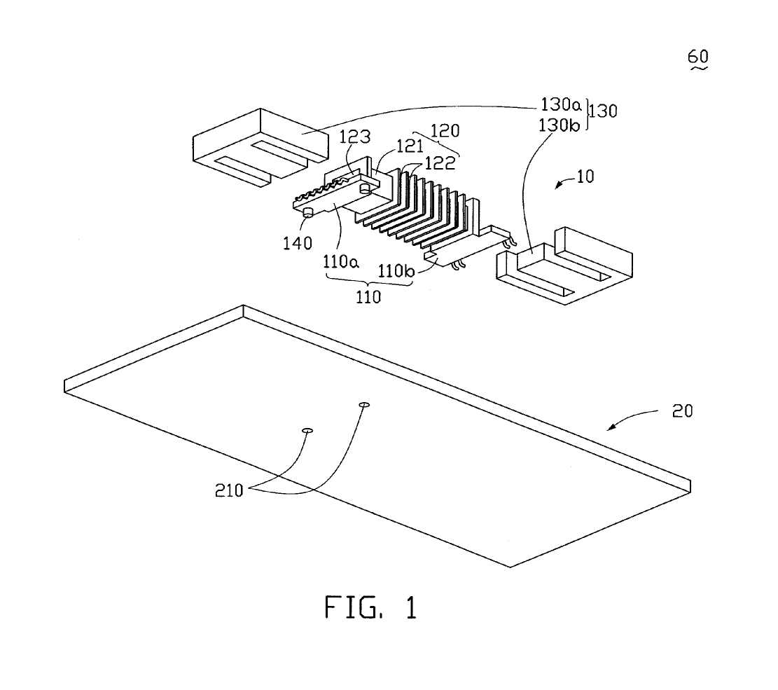

FIG. 1 shows an electronic device 60 of an exemplary embodiment of the present invention. The electronic device 60, such as an inverter, a converter, and the like, comprises a circuit part like a circuit board 20 and an electronic component like a transformer 10 coupled to the circuit board 20.

The transformer 10 comprises a base 110 mounted on the circuit board 20, a bobbin assembly 120, a core module 130, and two positioning means like two positioning posts 140. The base 110 comprises a first end portion 110a and a second end portion 110b opposite to the first end portion 110a. Both of them are able to electrically connectable to the circuit board 20. The bobbin assembly 120 is disposed between the first end portion 110a and the second end portion 110b. The bobbin assembly 120 comprises a first bobbin 121 having a primary winding wound thereon, and a second bobbin 122 having a secondary winding wound thereon. The second bobbin 122 is connected to the first bobbin 121. The first bobbin 121 is adjacent to the first end portion 110a, while the second bobbin 122 is adjacent to the second end portion 110b. The positioning posts 140 are disposed on opposite ends of the first end portion 110a.

The first bobbin 121 is disposed collinear with the second bobbin 122. The bobbin assembly 120 defines a hollow portion 123 extending therethrough. The core module 130 has a first core portion 130a and an opposite second core portion 130b, both of which are inserted in the hollow portion 123 from opposite ends of the bobbin assembly 120 to form a closed magnetic loop. Each of the core portions 130a and 130b has an E-shaped cross-section.

The circuit board 20 comprises two receiving holes 210 corresponding to the positioning posts 140. When the transformer 10 is coupled to the circuit board 20, the positioning posts 140 are received in the receiving holes 210. Thereby the transformer 10 is accurately positioned on the circuit board 20, facilitating soldering in a reflow oven.

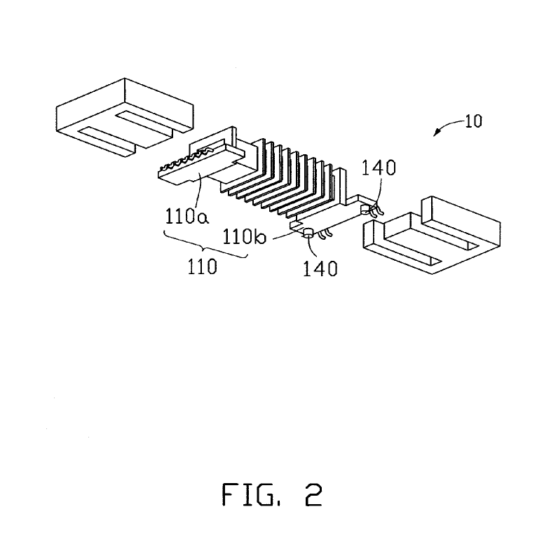

In another exemplary embodiment of the invention, referring to FIG. 2, the positioning posts 140 are disposed on the second end portion 110b of the base 110.

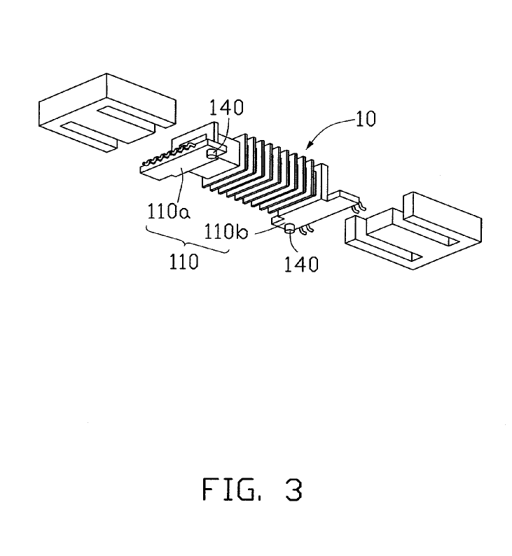

In a further exemplary embodiment of the invention, referring to FIG. 3, one of the positioning posts 140 is disposed on the first end portion 110a of the base 110, while the other is disposed on the second end portion 110b of the base 110.

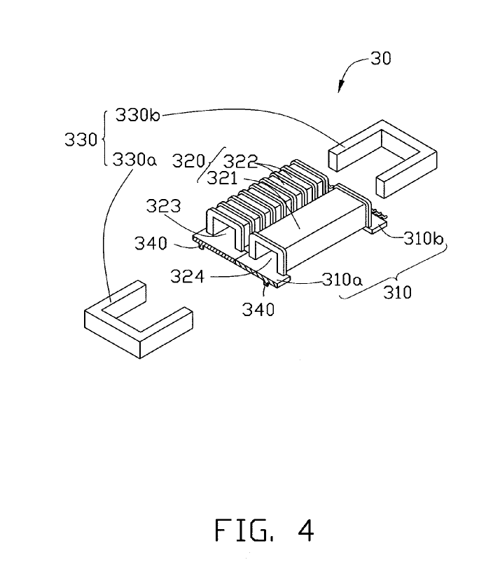

In a still further exemplary embodiment of the invention, referring to FIG. 4, a transformer 30 is shown. The transformer 30 comprises a base 310 having a first end portion 310a and a second end portion 310b opposite to the first end portion 310a, a bobbin assembly 320 having a first bobbin 321 and a second bobbin 322 parallel to the first bobbin 321, and two positioning posts 340. The bobbin assembly 320 is disposed between the first end portion 310a and the second end portion 310b. The first bobbin 321 defines a first hollow portion 324, while the second bobbin 322 defines a second hollow portion 323. The transformer 30 further comprises a core module 330 having a first core portion 330a and a second core portion 330b received in the hollow portions 324 and 323 respectively. Each of the core portions 330a and 330b has a U-shaped cross-section. The positioning posts 340 have a similar positioning means to that of the aforementioned exemplary embodiments of the present invention. When the transformer 30 is coupled to the circuit board 20 of FIG. 1, the positioning posts 340 are received in the receiving holes 210. As a result, the transformer 30 is accurately positioned on the circuit board 20, facilitating soldering in the reflow oven.

While exemplary embodiments have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A transformer, coupled to a circuit board defining a receiving hole, comprising:
a base comprising a first end portion and a second end portion opposite to the first end portion;
a bobbin assembly, disposed between the first end portion and the second end portion; and
at least one post, disposed on the base;
wherein the at least one post is received in the receiving hole for positioning the transformer on the circuit board.

2. The transformer as claimed in claim 1, wherein the at least one post is disposed on the first end portion of the base.

3. The transformer as claimed in claim 1, wherein the at least one post is disposed on the second end portion of the base.

4. The transformer as claimed in claim 1, wherein the at least one post comprises two posts.

5. The transformer as claimed in claim 4, wherein one of the two posts is disposed on the first end portion, while the other one of the two posts is disposed on the second end portion.

6. The transformer as claimed in claim 1, wherein the bobbin assembly comprises a first bobbin having a primary winding wound thereon, and a second bobbin having a secondary winding wound thereon.

7. The transformer as claimed in claim 6, wherein the first bobbin is adjacent to the first end portion of the base, and the second bobbin is adjacent to the second end portion of the base.

8. The transformer as claimed in claim 7, wherein the first bobbin is collinear with the second bobbin.

9. The transformer as claimed in claim 6, wherein the first bobbin and the second bobbin are arranged parallel to each other.

10. The transformer as claimed in claim 6, further comprising a core module, wherein each of the bobbins has a hollow portion for receiving the core module.

11. An electronic device, comprising:
a circuit board defining a receiving hole; and
a transformer, coupled to the circuit board, comprising:
a base comprising a first end portion and a oppositely disposed second end portion;
a bobbin assembly, disposed between the first end portion and the second end portion; and
at least one post, disposed on the base;
wherein the at least one post is received in the receiving hole for positioning the transformer on the circuit board.

12. The electronic device as claimed in claim 11, wherein the at least one post is disposed on the first end portion of the base.

13. The electronic device as claimed in claim 11, wherein the at least one post is disposed on the second end portion of the base.

14. The electronic device as claimed in claim 11, wherein the at least one post comprises two posts.

15. The electronic device as claimed in claim 14, wherein one of the two posts is disposed on the first end portion, while the other one of the two posts is disposed on the second end portion.

16. The electronic device as claimed in claim 11, wherein the bobbin assembly comprises a first bobbin having a primary winding wound thereon, and a second bobbin having a secondary winding wound thereon.

17. The electronic device as claimed in claim 16, wherein the first bobbin is adjacent to the first end portion of the base, and the second bobbin is adjacent to the second end portion of the base.

18. The electronic device as claimed in claim 17, wherein the first bobbin is collinear with the second bobbin.

19. The electronic device as claimed in claim 16, wherein the transformer further comprises a core module, and each of the bobbins has a hollow portion for receiving the core module.

20. An electronic device comprising:
a circuit assembly of said electronic device comprising circuitry performing functions of said electronic device; and
an electronic component comprising a base thereof to abut against said circuit assembly, said base comprising a first end portion and a second end portion orienting oppositely to said first end portion, both of which are electrically attachable to said circuit assembly to electrically connect with said circuitry of said circuit assembly, a bobbin assembly integrally formed in said component between said first and second end portions comprising windings wound thereon, and at least one positioning means selectively formed from said first and second end portions toward said circuit assembly in order to engage with said circuit assembly and attachably locate said component against said circuit assembly.
